(19) United States
(12) Patent Application Publication
(10) Pub. No.: US 2018/0269105 A1
(43) Pub. Date: Sep. 20, 2018

(54) BONDING OF III-V-AND-SI SUBSTRATES WITH INTERCONNECT METAL LAYERS

(71) Applicant: GLOBALFOUNDRIES Singapore Pte. Ltd., Singapore (SG)

(72) Inventors: Lawrence Selvaraj SUSAI, Singapore (SG); Donald Ray DISNEY, Cupertino, CA (US)

(21) Appl. No.: 15/459,162

(22) Filed: Mar. 15, 2017

(51) Int. Cl. H01L 21/8258; H01L 21/18; H01L 21/768; H01L 21/762

(52) U.S. Cl. CPC H01L 21/8258; H01L 21/762; H01L 21/768; H01L 21/187

(57) ABSTRACT

A III-V-and-Si substrate device is described including integration of a backend unit and a frontend unit. The backend unit includes interlevel dielectric (ILD) layers having metal lines and via contacts. The frontend unit includes a CMOS subunit bonded to a III-V subunit. A method of forming a III-V-and-Si substrate device comprises forming a backend unit in parallel with a frontend unit wherein the backend unit comprises a backend carrier substrate having interconnect metal layers disposed thereon forming a first surface, the frontend unit comprises a CMOS subunit and a III-V subunit wherein the CMOS subunit having a first and a second surface is bonded on the second surface to the III-V subunit on a first surface using bonding dielectrics; an bonding the backend unit on the first surface to the frontend unit on the first surfaces of the CMOS and the III-V subunits.

### BACKGROUND

Scaling of CMOS devices is becoming increasingly difficult because of increased number of devices in a small substrate area. Current silicon-based transistors are limited to about 14-22 nm technology nodes. Different semiconductor materials on the chip level or wafer level are necessary to overcome the scaling limits of silicon (Si) semiconductor. A semiconductor material may include two or more elements to form a compound semiconductor. For example, III-V compound semiconductors are compound semiconductors composed of elements from both Group III and Group V of the Periodic Table and can interact to form crystalline compounds. III-V semiconductors, such as gallium nitride (GaN) or indium gallium arsenide (InGaAs), have much higher electron mobility than silicon, and can be fashioned into faster, smaller, and lower-power transistors. These III-V semiconductors are already used in high-performance settings, such as light-emitting diodes (LEDs), high-electron-mobility transistors (HEMTs), and military radio transceivers. However, due to the higher production costs, susceptibility to density defects, and other factors, they have not made the leap to consumer products.

The heterogeneous integration of III-V semiconductor and Si semiconductor will enable the realization of radiofrequency (RF) and mixed signal circuits that take advantage of the superior performance of III-V semiconductor devices and the high integration density of Si semiconductor devices, such as complementary metal-oxide semiconductor (CMOS) on silicon. The increased device density in compound semiconductors requires higher power supply where reduction of power consumption and interconnect wiring length are challenging. A possible solution is to vertically stack the devices in a 3D integration scheme. 3D design requires direct bonding of III-V semiconductors on Si substrates (III-V-and-Si). Important issues need to be considered such as bonding surface smoothness, thermal budget, and reduction of current leakage. In addition, several back-end-of-line (BEOL) process steps must be completed after wafer bonding of III-V-and-Si CMOS processed wafer. Further, III-V-and-Si wafers are fragile and susceptible to breakage during BEOL process rendering the failure of process to directly integrate III-V-and-Si circuits at the wafer level.

For the above stated reasons, it is desirable to simplify and de-risk the integration process of III-V semiconductor devices with Si semiconductor devices to leverage on the mature Si technology.

### SUMMARY OF THE INVENTION

This invention generally relates to semiconductor wafer bonding and more particularly, but not limited to, methods of bonding a silicon wafer to a III-V semiconductor wafer. The III-V-and-Si substrate device is a 3D integration of a silicon transistor and a III-V substrate transistor. For example, the silicon transistor may be a CMOS transistor and the III-V transistor may be a GaN transistor.

A III-V-and-Si substrate device includes integration of a backend unit and a frontend unit. The backend unit and frontend unit are formed in parallel. The backend unit includes interlevel dielectric (ILD) layers having metal lines and via contacts. The ILD layers are formed on a backend carrier substrate, such as silicon, having the uppermost ILD level disposed on a dielectric layer sequentially to the lowest ILD level, with the uppermost level metal line on the bottom closest to the backend carrier substrate and lowest level metal line on the top.

The frontend unit includes a CMOS subunit and a III-V subunit. A CMOS subunit includes CMOS devices disposed in a first surface of a silicon wafer substrate. Bonding dielectric layers are formed on first and second surfaces of the substrate. A III-V subunit includes III-V devices disposed in a first surface of a III-V wafer substrate. A III-V wafer substrate includes a III-V layer disposed on a silicon substrate with a buffer layer there between. The III-V subunit has bonding dielectric layers covering the III-V devices on the first surface.

In one embodiment, for example Approach 1, the frontend unit is formed by bonding a processed CMOS subunit and an unprocessed III-V subunit. The second surface of CMOS subunit is bonded to the first surface of the III-V subunit. III-V device regions are exposed on the III-V substrate by removing a portion of CMOS substrate using mask and etch techniques. III-V devices are then formed in the III-V device regions. A pre-metal dielectric layer (PMD) of the CMOS subunit is continuous with and having the same height as a dielectric layer covering the III-V subunit. A frontend unit includes first level metal lines disposed on top of the dielectric layer connecting to the CMOS and III-V subunits, using via contacts.

In another embodiment, for example Approach 2, a III-V substrate is processed before bonding to a processed CMOS subunit. III-V devices are disposed in a first surface of the III-V substrate and covered by bonding dielectric layers. The second surface of the CMOS subunit is bonded to the first surface of the III-V subunit. A PMD of the CMOS subunit is continuous with and having the same height as a dielectric layer covering the III-V subunit. A frontend unit includes first level metal lines disposed on top of the dielectric layer connecting to the CMOS and III-V subunits, using via contacts.

The frontend unit formed, for example in Approach 1 or Approach 2, is bonded to the backend unit to form the III-V-and-Si substrate device. Bonding dielectrics include silicon oxides, silicon nitrides, aluminum oxides, or a combination thereof. The bonding processes are generally performed by fusing bonding dielectric layers under low temperatures and followed by an anneal, for example, thermo-anodic or anodic bonding. Bonding surfaces have high smoothness before bonding. Multiple bonding and annealing steps may be performed from a lower temperature to a higher temperature. Substrates may be thinned after bonding to relieve thermal tension from mismatched thermal coefficients of the substrates.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. Various embodiments of the present invention are described with reference to the following drawings, in which:

FIGS. 1a-1c show a simplified schematic view of a III-V-and-Si substrate integrated device;

FIGS. 2a-2d show an exemplary process of forming a CMOS subunit of the frontend unit;

FIGS. 3a-3d show an exemplary process of forming a processed III-V subunit of the frontend unit;

FIG. 4 shows a simplified schematic view of an unprocessed III-V subunit of the frontend unit;

FIGS. 5a-5b show an exemplary process of forming a backend unit with a backend unit bonded to a backend carrier substrate;

FIGS. 6a-6g show an exemplary Approach 1 of bonding a processed CMOS subunit with an unprocessed III-V subunit;

FIGS. 7a-7f show an exemplary Approach 2 of bonding a processed CMOS subunit with a processed III-V subunit; and

FIGS. 8a-8b show an exemplary process of bonding a backend unit to a frontend unit in Approach 1 or Approach 2.

### DETAILED DESCRIPTION OF THE INVENTION

Embodiments generally relate to semiconductor devices or integrated circuits (ICs). More particularly, some embodiments relate to heterogeneous integration of devices by bonding a silicon (Si) wafer to a III-V semiconductor wafer. For example, the silicon wafer may include silicon devices, such as, but not limited to, metal oxide transistors (MOS), or complementary metal oxide transistors (CMOS). The III-V wafer may include III-V compound devices such as, but not limited to, gallium nitride (GaN) or indium gallium arsenide (InGaAs) devices. The integration of GaN and Si wafers may be employed in analog applications, such as DC/DC converters with GaN output switches, integrated RF frontend with GaN power amplifiers, Class-D amplifiers with GaN output switches, LED drivers integrated with LEDs for advanced displays, high performance analog to digital converters, audio amplifiers or audio Codex. These high gain transistors can be easily integrated into devices or ICs with core or digital devices.

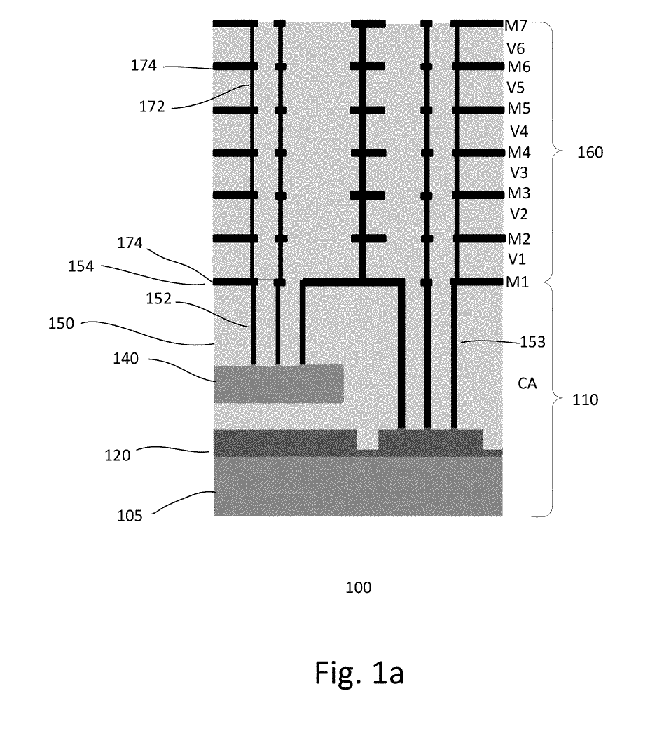

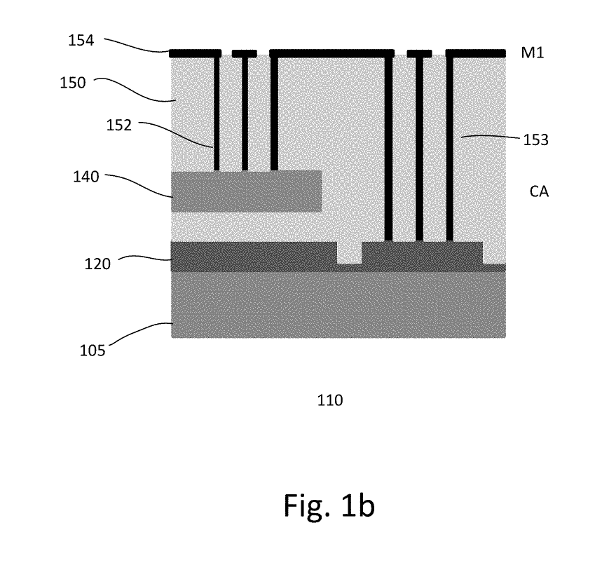

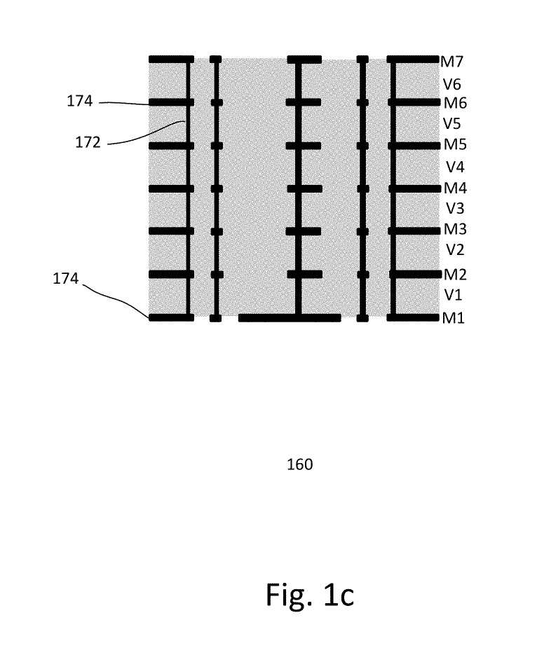

FIGS. 1a-1c show a simplified schematic view of an exemplary III-V-and-Si substrate integrated device 100. Device 100 includes a frontend unit 110 and a backend unit 160. The frontend unit 110 includes a III-V subunit 120 disposed on a silicon base substrate 105 which is part of the III-V subunit. The frontend unit also includes a CMOS subunit 140 disposed in a silicon wafer substrate. The silicon substrate includes a first (front side) surface and a second (back side) surface. Front-end-of-line (FEOL) processing is performed on the first surface of the substrate. The FEOL process, for example, forms n-type and p-type transistors, such as CMOS transistors. The FEOL processing, for example, includes forming isolation regions, various device and isolation wells, transistor gates and transistor source/drain (S/D) regions and contact or diffusion regions serving as substrate or well taps. Forming other components with the FEOL process may also be useful.

Isolation regions, for example, serve to isolate different device regions. The isolation regions may be shallow trench isolation (STI) regions. To form STI regions, trenches are formed and filled with isolation dielectric material. A planarization process, such as chemical mechanical polishing (CMP) is performed to remove excess dielectric material, forming isolation regions. Other types of isolation regions may also be useful. Isolation regions may be provided to isolate columns of memory cells. The device well may be a common well for the device regions in the array region. For example, the device well may be an array well. The device isolation well may serve as the array isolation well. Other configurations of device and isolation wells may also be useful. Other device regions of the device may also include device and/or device isolation wells.

As shown in FIG. 1a, device 100 includes a CMOS subunit 140 and a III-V subunit 120. The CMOS and III-V subunits may have devices disposed in wafer substrates. The III-V wafer substrate may also serve as a base substrate 105. The wafer substrate, for example, is a silicon substrate. Other types of substrates, such as silicon germanium, germanium, gallium arsenide, or crystal-on-insulator (COI) such as silicon-on-insulator (SOI), are also useful. The substrate may be a doped substrate. For example, the substrate can be lightly doped with p-type dopants. Providing a substrate with other types of dopants or dopant concentrations, as well as an undoped substrate, may also be useful.

The device may include doped regions having different dopant concentrations. For example, the device may include heavily doped (x+), intermediately doped (x) and lightly doped (x-) regions, where x is the polarity type which can be p or n. A lightly doped region may have a dopant concentration of about 1E15-1E17/cm³, an intermediately doped region may have a dopant concentration of about 1E17-1E19/cm³, and a heavily doped region may have a dopant concentration of about 1E19-1E21/cm³. Providing other dopant concentrations for the different types of doped regions may also be useful. For example, the ranges may be varied, depending on the technology node. In addition, the ranges may vary based on the type of transistors or devices, such as high voltage, intermediate voltage or low voltage transistors. P-type dopants may include boron (B), aluminum (Al), indium (In) or a combination thereof, while n-type dopants may include phosphorous (P), arsenic (As), antimony (Sb) or a combination thereof.

A device well (not shown) may be disposed in a device region. A device well is a second polarity type doped well which serves as a body for a first polarity type device. For example, a p-type device well is provided for a n-type transistor or a n-type device well is provided for a p-type transistor. In some cases, a device well may be provided by the starting substrate. For example, if the starting substrate includes the appropriate doping type and concentration, it may serve as a device well. The dopant concentration of the device wells may be light to intermediate. In one embodiment, the different types of device wells have different dopant concentrations.

A gate of a transistor is disposed on the substrate surface in the device region. For example, the gate is disposed over the device well. A gate includes a gate electrode over a gate dielectric. The gate electrode, for example, may be polysilicon while the gate dielectric may be silicon oxide. Other types of gate electrodes or gate dielectrics may also be useful. For example, the gate electrode may be a metal gate electrode and the gate dielectric may be a high k gate dielectric. Dielectric sidewall spacers are disposed on sidewalls of the gate. The sidewall spacers, for example, may be silicon oxide. Other types of dielectric materials or combination of materials may be used for the spacers.

A transistor includes first and second source/drain (S/D) regions disposed in the device well adjacent to the first and second sides of the gate. In one embodiment, a S/D region includes a main S/D region and an extension S/D region. The main and extension regions are first polarity type doped regions. The main region is a heavily doped region while the extension region is a lightly doped region. The extension S/D region may be referred to as a lightly doped drain (LDD) extension region. The main S/D region is disposed adjacent to about an outer edge of the dielectric sidewall spacer and the gate overlaps the extension region. The gate, for example, overlaps the extension region by about 10 Å. Overlapping the extension region by other distances may also be useful.

Mask and implant techniques may be employed to form the main S/D regions in the device region. For example, a mask exposing the device region is used for the implant. The implant forms heavily doped main S/D regions in the device region. The dopant concentration of the main S/D region may be about 1E20/cm³. The main S/D regions may have a depth of about 200 nm. Other dopant concentrations and depths for the main S/D regions may also be useful. After forming the main S/D regions, the implant mask is removed by, for example, ashing. Other techniques for removing the implant mask may also be useful.

After forming the S/D regions, an annealing process, such as rapid thermal anneal (RTA), may be performed to activate the dopants in the S/D regions. The inner edges of the doped regions, for example, may extend under the dielectric spacers due to diffusion of the dopants from the doped regions.

In some embodiments, a dielectric etch stop layer is formed over the transistors. The etch stop layer, for example, is a silicon nitride etch stop layer. Other types of etch stop layers may also be useful. The etch stop layer should have a material which can be selectively removed from a dielectric layer thereover. The etch stop layer facilitates in forming contact plugs to contact regions of the transistor, such as the gate electrode and doped regions. In some embodiments, the etch stop layer may also serve as a stress layer for applying a stress on the channel of the transistor to improve performance.

Metal silicide contacts may be formed on the S/D regions and on the gate electrodes. The metal silicide contacts, for example, may be nickel-based contacts. Other types of metal silicide contacts may also be useful. For example, the metal silicide contact may be cobalt silicide (CoSi). The silicide contacts may be about 50-300 Å thick. Other thicknesses may also be useful. The metal silicide contacts may be employed to reduce contact resistance and facilitate contact to the BEOL metal interconnects. For example, a dielectric layer 150 may be provided over the transistors. Via contacts, such as tungsten contacts, may be formed in the dielectric layer coupling the contact regions of the transistors to metal lines disposed in metal layers of the device.

Shown in FIGS. 1a-1b, the frontend unit 110 also includes a III-V subunit 120. The III-V subunit is disposed on a base substrate 105. The base substrate, for example, is a silicon substrate. Other types of substrates, such as silicon germanium, germanium, gallium arsenide, or crystal-on-insulator (COI) such as silicon-on-insulator (SOI), are also useful. The substrate may be a doped substrate. For example, the substrate can be lightly doped with p-type dopants. Providing a substrate with other types of dopants or dopant concentrations, as well as an undoped substrate, may also be useful.

A buffer layer may be formed on the base substrate 105 and a III-V layer is formed thereover. The buffer layer is used as a transition layer to accommodate the lattice mismatch of the base substrate and III-V layer. Buffer and the III-V layers may be formed by metal-organic chemical vapor deposition (MOCVD) or molecular beam epitaxy (MBE). MOCVD/MBE is used to deposit very thin layers of III-V molecules or atoms onto a semiconductor wafer. The wafers, for example, may be thin disks mostly made of sapphire or silicon. III-V compounds include gallium arsenide (GaAs), indium phosphide (InP), gallium nitride (GaN) and related alloys. Buffer layers, for example, may include aluminium oxide (Al₂O₃), aluminum nitride (AlN), aluminium indium arsenide (AlInAs), GaN, indium gallium nitride (InGaN) or other oxides or nitrides. The chemicals are vaporized and transported into the reactor together with other gases. There, the critical chemical reaction takes place that turns the chemicals into the desired crystal (the III-V compound semiconductor). The layers may be built up with each layer of a precisely controlled thickness. For example, using existing silicon processing equipment, a thin layer of AlN is grown on the silicon to isolate the device structure from the substrate. A thick layer of highly resistive GaN is grown thereover. This layer provides a foundation on which to build the GaN transistor. An electron generating material is applied to the GaN. For example, a barrier layer, such as aluminium gallium arsenide (AlGaN), is built over the GaN layer. This AlGaN layer creates a GaN layer with an abundance of electrons at the interface of AlGaN/GaN that is highly conductive. Other materials may also be used in barrier and for the III-V layers.

As such, compound semiconductors have significant advantages over silicon. Devices containing III-V semiconductors can “process” very high frequencies in devices, for examples, in mobile phone, because electrons can move very fast in III-V materials. Moreover, they can also function at very high temperatures. Most importantly, they are highly efficient at converting light energy to electrical energy and vice-versa—the basis for high-performance solar cells and all LEDs.

The III-V semiconductor wafer has a plurality of isolation regions formed therein by photolithography and etch processes. The isolation regions define active device regions where active III-V devices will be disposed. In one embodiment, the device regions in the III-V substrate are isolated from other regions by isolation regions. The isolation regions may be shallow trench isolation (STI) trenches. Other isolation regions may also be useful. For example, the isolation regions may be deep trench isolation (DTI) regions. The STI regions, for example, extend to a depth of about 2000-5000 Å. Providing isolation regions which extend to other depths may also be useful.

A mesa is formed in the device region of the III-V layer by etching away, with the aid of a reactive gas plasma, the semiconductor material surrounding a masked area. Other mesa etching techniques may also be employed, such as wet chemical etching and fast atom beam etching. After mesa formation and while the etch-masking layer is in place, the exposed silicon is subjected to an oxidation treatment to grow a dielectric passivation layer. After the passivation formation, the mask layer is removed by etching method, for example, acid etching with phosphoric acid.

Source and drain (S/D) ohmic contacts (not shown) are formed in the device region typically by depositing thin metal films of a carefully chosen composition, possibly followed by annealing. For example, GaN ohmic contact materials include Ti/Al/Ni/Au, Pd/Au. These metal-semiconductor ohmic contacts are made by direct contact between the metals without intervening insulating or oxidation layers. Other techniques such as sputtering, CVD, PVD, electron beam evaporation, electroplating or others are also useful. A metal contact is formed for gate Schottky contact using similar techniques. Barrier layers are disposed above and below the gate to isolate the gate and source and drain regions. Both ohmic and Schottky contacts are dependent on the Schottky barrier height which sets the threshold for the excess energy an electron requires to pass from the semiconductor to the metal. For the junction to admit electrons easily in both directions (ohmic contact), the barrier height must be small in at least some parts of the junction surface.

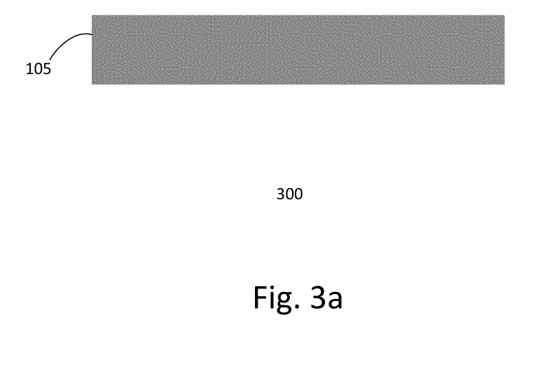

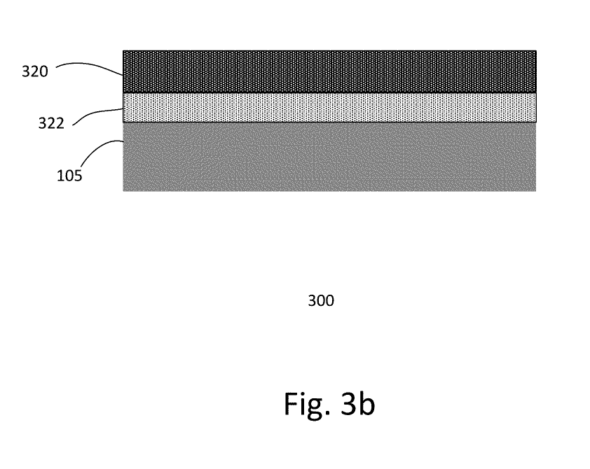

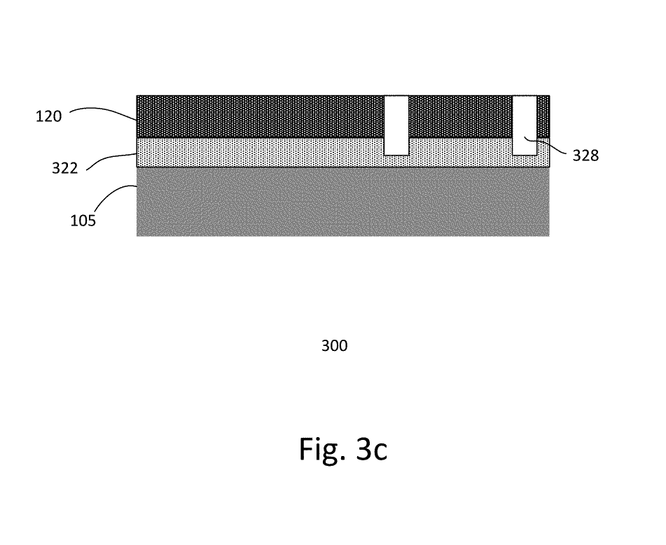

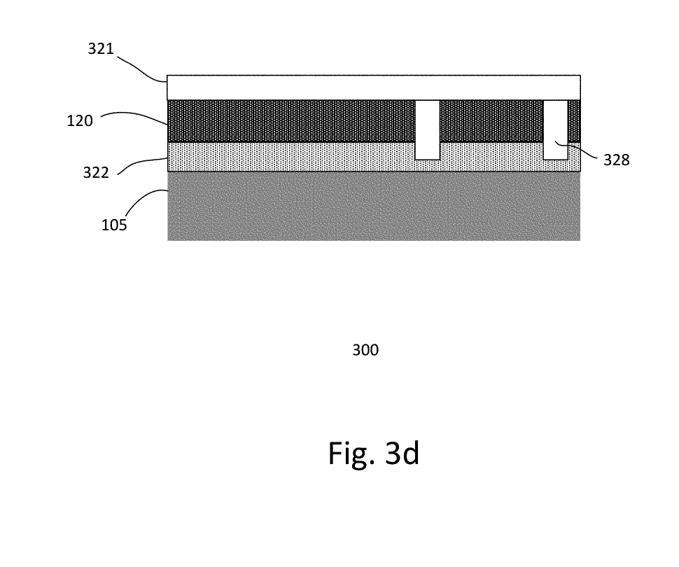

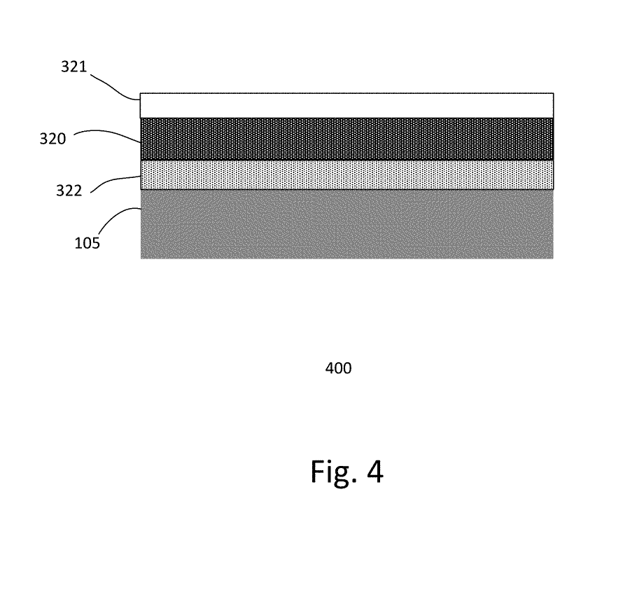

The bonding dielectric layer is then formed on III-V semiconductor wafer and in STIs by a deposition process. The preferred embodiment of bonding dielectric layer comprises a nitride/oxide layer. After the bonding dielectric layer is formed, a planarizable layer (not shown) may be formed over the bonding dielectric layer. Planarizable layer may comprise polysilicon, silicon nitride, or reflowable glass. In one embodiment, planarizable layer may not fill the STI previously filled by dielectric materials in a processed III-V device (FIG. 3d). In another embodiment, planarizable layer may fill the STI to form an unprocessed III-V substrate to be processed later (FIG. 4). FIG. 3d represents the III-V semiconductor wafer which has completed the device isolation process whereas, FIG. 4 shows the III-V wafer without a device isolation. The planarizable layer may then be planarized. After bonding, a portion of the bonding dielectric layer or planarizable layer may be removed from an unprocessed III-V substrate to expose the III-V device regions for further processing.

Continuing with FIG. 1b, a CMOS subunit 140 and a III-V subunit 120 are bonded to form the frontend unit 110. Frontend units are formed in a FEOL process. As described above, a CMOS subunit 140 includes a CMOS device (not shown) disposed on a first surface (top surface) of a silicon substrate. A III-V subunit includes a III-V device 120 disposed on a first surface of a III-V base substrate 105. CMOS subunit 140 is bonded on a second surface (bottom surface) to the first surface (top surface) of a III-V subunit 120. CMOS and III-V devices include gate, S/D regions. For example, CMOS devices may employ polysilicon or metal silicide gates. III-V devices may employ metal gates. Metal silicide contacts are disposed on the gate and S/D regions. A dielectric layer 150 covers the CMOS and III-V subunits to a same height. This dielectric layer is referred to as pre-metal dielectric (PMD) level or CA level. Via contacts connect to the subunits in the CA level. For example, contacts 152 connect to CMOS subunit 140, and contacts 153 connect to III-V subunit 120. A first level metal line (M₁) 154 is formed on top of the CA level and connects to the CMOS and III-V subunits by the via contacts 152 and 153.

The backend unit 160 is illustrated in FIG. 1c. The BEOL process is conducted in parallel with the FEOL process. The backend unit includes interlevel dielectric (ILD) layers in ILD levels. The ILD levels of backend unit are electrically connected by via contacts 172 in via levels and metal lines 174 in metal levels.

An ILD level includes a metal level and a via level. Generally, the metal level includes conductors or metal lines while the via level includes via contacts. The conductors and contacts may be formed of a metal, such as copper, copper alloy, aluminum, tungsten or a combination thereof. Other suitable types of metal, alloys or conductive materials may also be useful. In some cases, the conductors and contacts may be formed of the same material, for example, where the conductors and contacts are formed by dual damascene processes. In some cases, the conductors and contacts may have different materials, for example, where the contacts and conductors are formed by single damascene processes. Other techniques, such as reactive ion etch (RIE) may also be employed to form metal lines.

A backend unit may include a plurality of ILD layers or levels. For example, x number of ILD levels may be provided. As illustrated in FIG. 1c, the die includes 7 ILD levels (x=7). Other suitable number of ILD levels may also be useful. The number of ILD levels may depend on, for example, design requirements or the logic process involved. A metal level of an ILD level may be referred to as Mᵢ, where i is from 1 to x and is the i^{th} ILD level of x ILD levels. A contact level of an ILD level may be referred to as Vᵢ₋₁, where i is the i^{th} ILD level of x ILD levels. The ILD layers may be formed of silicon dioxide. Other types of dielectric materials, such as low k, or a combination of dielectric materials may also be useful. The ILD layers may be formed by, for example, CVD. Other techniques for forming the ILD layers may also be useful.

The upper ILD layer may have different design rules, such as critical dimension (CD), than the intermediate ILD layers. For example, upper ILD layer may have a larger CD than the intermediate ILD layers. For example, the upper ILD layer may have a CD which is 2x or 6x the CD of the intermediate ILD layers. Shown in FIG. 1c, one or more metal lines 174 are disposed in the metal level dielectric 160 while one or more via contacts 172 are disposed in the via level dielectric 160 of the ILD level. The top level contact is disposed in the via level Vₓ₋₁ (V₆) in between the uppermost metal level Mₓ (M₇) and its adjacent underlying lower metal level Mₓ₋₁ (M₆). Metal lines of the uppermost ILD level may be about 2x to 6x larger and thicker than metal lines (not shown) in intermediate or lower ILD layers.

Metal lines are formed by patterning and lithographic techniques. Metal conductive layers are deposited on the ILD dielectric layer. A soft mask layer is formed on the conductive layer. The soft mask layer, in one embodiment, is a photoresist layer. The soft mask is patterned to form openings while covering portions of the conductive layer. To form the openings in the soft mask layer, it may be selectively exposed with an exposure source using a reticle. The pattern of the reticle is transferred to the photoresist layer after exposure by a development process. An anti-reflective coating (ARC) may be provided beneath the resist layer to improve lithographic resolution. The patterned resist layer serves as an etch mask. For example, an anisotropic etch, such as RIE, patterns the conductive layer using the etch mask. The patterned resist is used to define one or more metal lines by removing portions of the conductive layer not protected by the patterned resist. The portion of the conductive layer under the patterned resist remains and forms the metal line 174 as shown in FIG. 1c. The metal line 174x-i, for example, may correspond to metal line of metal level Mₓ₋₁, where Mₓ₋₁ is the underlying metal level of the uppermost metal level Mₓ. The metal line, as shown, is formed by subtractive etch process. Other suitable techniques for forming the one or more metal lines may also be useful, depending on the material of the metal lines. For example, in the case where the metal lines include Cu, the metal lines may be formed by damascene technique (not shown). The patterned mask is removed using suitable techniques, such as ashing, after forming the metal line.

Via contacts are formed from one or more via openings through the dielectric layer. To form one or more via openings, mask and etch techniques can be employed. For example, a mask, such as a photoresist, can be used to form the via opening. The mask is selectively exposed and developed to create the desired via opening patterns. The mask, for example, includes a pattern which protects or covers the dielectric layer except where via openings are to be formed. Exposed portions of the dielectric layer are removed by, for example, a dry etch or RIE. For example, via opening is formed through the dielectric layer and the underlying dielectric layer, exposing portion of the metal line 174ₓ₋₁. Tungsten materials may be deposited in the via openings to form the via contacts 172ₓ. The mask is removed using suitable techniques, such as ashing.

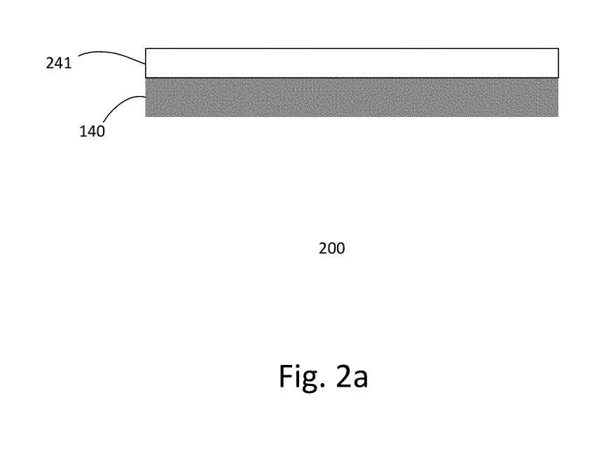

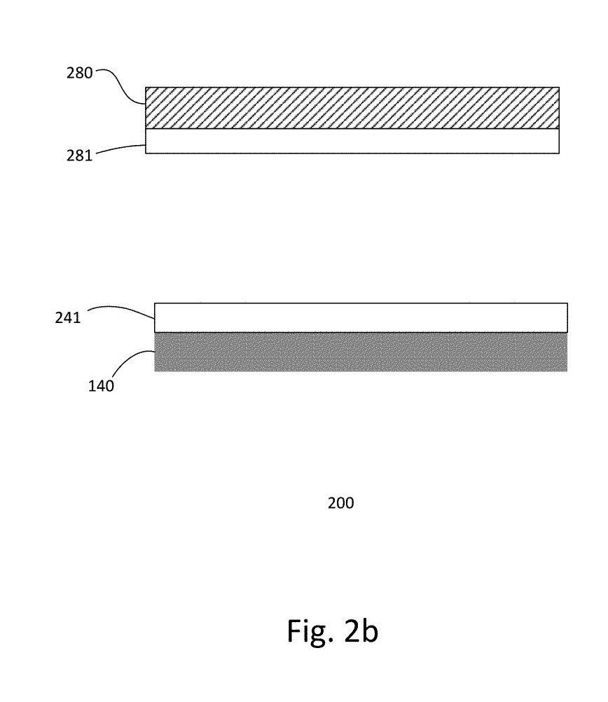

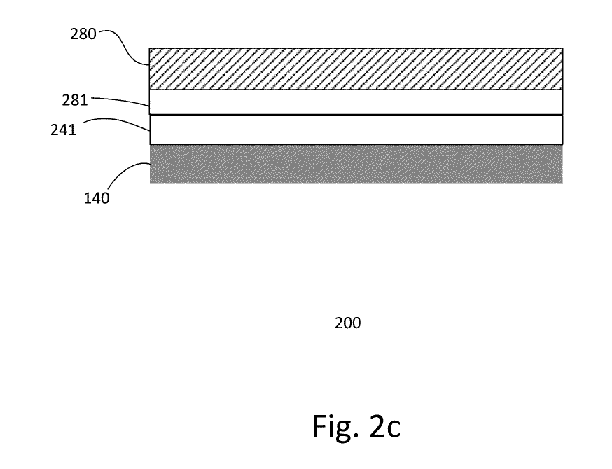

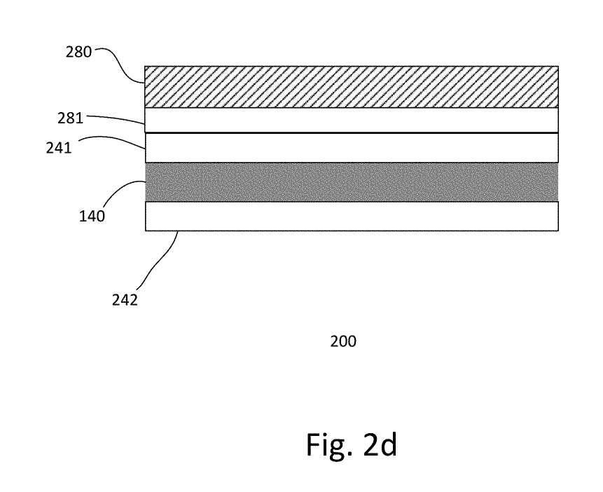

In FIGS. 2a-2d, process 200 illustrates an exemplary process of forming a CMOS subunit 140 as a component for the frontend unit 110. In FIG. 2a, a CMOS substrate is provided having CMOS devices (not shown) disposed therein to form the CMOS subunit 140 for device 100 as described in FIGS. 1a-1c. Common elements are incorporated by reference and will not be described in detail. A bonding dielectric layer 241 is formed on a first surface of the processed CMOS substrate 140. The bonding dielectric layer may be silicon oxide, silicon nitride, or layers of combination formed by chemical vapor deposition (CVD). Bonding dielectric layers made of other materials may also be useful.

In FIG. 2b, a carrier substrate 280 is provided, for example, a silicon substrate. A bonding dielectric layer 281 is formed on a surface of the carrier substrate. The bonding surfaces of the wafers have to exhibit low roughness and the materials used must also have good electrical isolation to act as the inter wafer dielectric. The bonding dielectric layer may be aluminum oxide (Al₂O₃), silicon oxide (SiO₂) or silicon nitride (SiN) formed by CVD. Bonding dielectric layers made of other materials may also be useful.

FIG. 2c illustrates the bonding of a processed CMOS substrate and a carrier substrate. For example, room temperature bonding of 100 mm wafers using Al₂O₃ and different oxides as the carrier wafer bonding dielectric layer. Al₂O₃ grown by atomic layer deposition (ALD) at 350° C. exhibits good conformity. Other deposition methods such as plasma enhanced chemical vapor deposition (PECVD) may also be useful. When a 100 nm ALD SiO₂ is introduced in the dielectric stack, it acts as a stop layer for the defects and binds well with the Al₂O₃ of the carrier wafer. The CMOS silicon devices have a thermal budget limited to 400-500° C. The wafer bonding is performed at room temperature and enhanced by a short annealing that does not exceed the required thermal budget.

After the carrier substrate is bonded to the first surface of a processed CMOS substrate, a bonding dielectric layer 242 is formed on the second surface of the CMOS substrate as shown in FIG. 2d. Al₂O₃ or different oxides may be used as the CMOS substrate wafer bonding dielectric layer. Al₂O₃ grown by ALD at 350° C. exhibits good conformity. Other deposition methods such as PECVD may also be useful. This bonded processed CMOS substrate wafer will be used in the subsequent steps in forming the III-V-and-Si substrate devices.

FIGS. 3a-3d show an exemplary process 300 of forming a processed III-V subunit 120 of the frontend unit 110 of device 100 as described in FIGS. 1a-1c. Common elements are incorporated by reference and will not be described in detail. Process 300 begins with a base substrate 105 in FIG. 3a. The substrate, for example, is a silicon substrate. Other types of substrates, such as silicon germanium, germanium, gallium arsenide, or crystal-on-insulator (COI) such as silicon-on-insulator (SOI), are also useful. The substrate may be a doped substrate. For example, the substrate can be lightly doped with p-type dopants. Providing a substrate with other types of dopants or dopant concentrations, as well as an undoped substrate, may also be useful.

FIG. 3b illustrates a buffer layer 322 formed on the base substrate 105 and a III-V layer 320 formed thereover. The buffer layer is used as a transition layer to accommodate the lattice mismatch of the base substrate and III-V layer. Buffer and the III-V layers may be formed by metal-organic chemical vapor deposition (MOCVD) or molecular beam epitaxy (MBE). MOCVD/MBE is used to deposit very thin layers of III-V molecules or atoms onto a semiconductor wafer. The wafers, for example, may be thin disks mostly made of sapphire or silicon. III-V compounds include Gallium Arsenide (GaAs), Indium Phosphide (InP), Gallium Nitride (GaN) and related alloys. Buffer layers, for example, may include Al₂O₃, AN, AlInAs, GaN, InGaN or other oxides or nitrides. The chemicals are vaporized and transported into the reactor together with other gases. There, the critical chemical reaction takes place that turns the chemicals into the desired crystal (the III-V compound semiconductor). The layers may be built up with each layer of a precisely controlled thickness. For example, using existing silicon processing equipment, a thin layer of aluminum nitride (AlN) is grown on the silicon to isolate the device structure from the substrate. A thick layer of highly resistive GaN is grown thereover. This layer provides a foundation on which to build the GaN transistor. An electron generating material is applied to the GaN. For example, a barrier layer, such as AlGaN, is built over the GaN layer. This AlGaN layer creates a GaN layer with an abundance of electrons at the interface of AlGaN/GaN that is highly conductive. Other materials may also be used in barrier and III-V layers.

The process continues in FIG. 3c, the III-V semiconductor wafer has a plurality of isolation regions formed therein by photolithography and etch processes. In one embodiment, the device regions in the III-V substrate are isolated from other regions by isolation regions 328. The isolation regions define active device regions where the active III-V devices are disposed. The isolation regions may be shallow trench isolation (STI) regions. Other isolation regions may also be useful. For example, the isolation regions may be deep trench isolation (DTI) regions. The STI regions, for example, extend to a depth of about 2000-5000 Å. Providing isolation regions which extend to other depths may also be useful.

A mesa is formed by etching away, with a reactive gas plasma, the semiconductor material surrounding a masked area. Other mesa etching techniques may also be employed, such as wet chemical etching and fast atom beam etching. After mesa formation and while the etch-masking layer is in place, the exposed III-V region is subjected to an oxidation treatment to grow a dielectric passivation layer. After the passivation formation, the masking layer is removed by etching method, for example, acid etching with phosphoric acid. III-V devices are disposed in the III-V region between the isolation regions 328 as part of the III-V subunit 120.

S/D ohmic contacts (not shown) are formed in the device region typically by depositing thin metal films of a carefully chosen composition, possibly followed by annealing. For example, GaN ohmic contact materials include Ti/Al/Ni/Au, Pd/Ti/Au. These metal-semiconductor ohmic contacts are made by direct contact between the metals without intervening insulating or oxidation layers. Other techniques such as sputtering, CVD, PVD, electron beam evaporation, electroplating or others are also useful. A metal contact is formed for gate Schottky contact using similar technique. Barrier layers are disposed above and below the gate to isolate the gate and S/D regions. Both ohmic and Schottky contacts are dependent on the Schottky barrier height which sets the threshold for the excess energy an electron requires to pass from the semiconductor to the metal. For the junction to admit electrons easily in both directions (ohmic contact), the barrier height must be small in at least some parts of the junction surface.

The bonding dielectric layer 321 is then formed on III-V semiconductor wafer and in STIs by a deposition process. The preferred embodiment of bonding dielectric layer comprises a nitride/oxide layer. After the bonding dielectric layer is formed, a planarizable layer (not shown) may be formed over the bonding dielectric layer. The planarizable layer may comprise polysilicon, silicon nitride, or reflowable glass. In one embodiment, the planarizable layer 321 may not fill the STI previously filled by dielectric materials in a processed III-V device (FIG. 3d). In an alternative embodiment, the bonding dielectric layer 321 may cover the III-V layer 320 to form an unprocessed substrate to be processed later (FIG. 4). FIG. 3d represents the III-V semiconductor wafer which has completed the device isolation process whereas, FIG. 4 shows the III-V wafer without a device isolation. The planarizable layer may then be planarized. After bonding, a portion of bonding dielectric layer or planarizable layer may be removed from an unprocessed III-V substrate to expose the III-V device regions for further processing.

As such, a bonding dielectric layer 321 is formed on the first surface of the processed III-V semiconductor substrate wafer as shown in FIG. 3d. Alternatively, a bonding dielectric layer 321 is formed on the first surface of an unprocessed III-V substrate wafer, as shown in FIG. 4, where semiconductor devices may be fabricated on a III-V semiconductor substrate wafer in later processes. The III-V subunit formed in process 300 or 400 is ready for bonding to CMOS subunit to form the frontend unit in Approach 1 or Approach 2, for example, which will be described later in this disclosure.

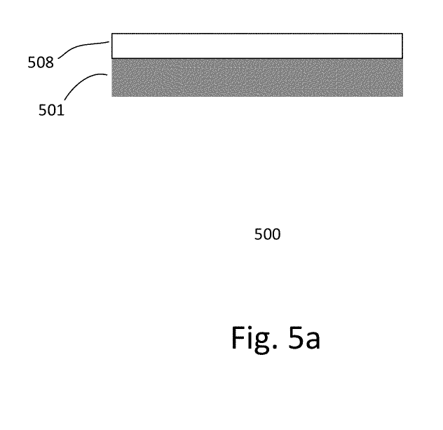

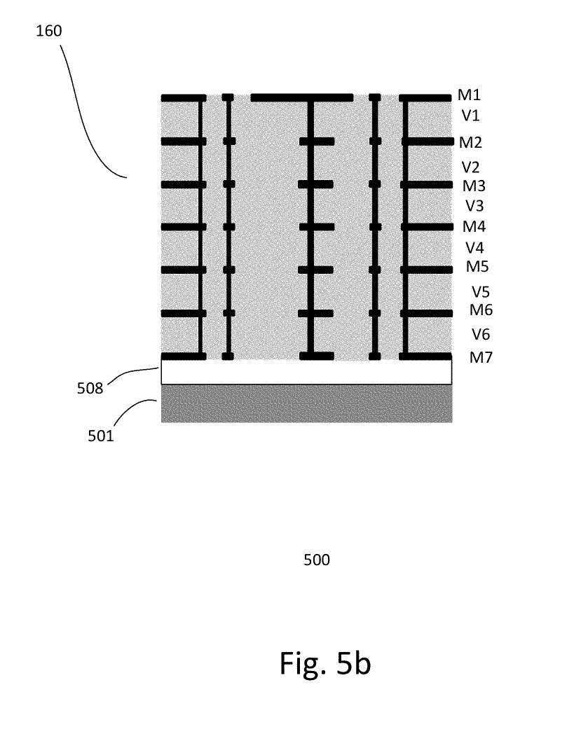

FIGS. 5a-5b show the process 500 of forming a backend unit 160 for device 100 as described in FIGS. 1a-1c. Common elements are incorporated by reference and will not be described in detail.

In FIG. 5a, the BEOL process is conducted in parallel with the FEOL process. The BEOL process 500 starts with a back end carrier substrate 501. The carrier substrate may be silicon, or other substrates. A dielectric layer 508 is formed on the carrier substrate 501 as a buffer. The dielectric layer may be, for example, silicon dioxide formed by CVD. Other materials may also be useful. BEOL processing includes forming interconnects in ILD layers over the dielectric layer of the carrier substrate. The interconnects connect various components of the IC to perform the desired functions.

Shown in FIG. 5b, conductive lines are formed sequentially, starting from the uppermost ILD level down to the lowest ILD level, for example, M₇ to M₁. The conductive lines in M₇ level may be formed on the dielectric layer over the carrier substrate. The M₇ conductive lines may be formed by a single damascene technique using, for example, mask and etch techniques. The process continues to form additional ILD layers. For example, in the case where x=7 (7 levels), the additional levels include ILD levels from 6 to 1, which include metal levels M₆ to M₁ and via levels V₆ to V₁. The number of ILD layers may depend on, for example, design requirements or the logic process involved. The conductive lines in other levels such as M₆ and V₆ levels down to M₁ and V₁ levels, may be formed by dual damascene techniques using, for example, mask and etch techniques The conductive material such as copper or copper alloy may be formed by, for example, plating, such as electro or electroless plating.

Continuing with FIG. 5b, the conductors and contacts of the additional ILD layers may be formed by dual damascene techniques. For example, vias and trenches are formed, creating dual damascene structures. The dual damascene structure may be formed by via first or via last techniques. Mask and etch techniques may be employed to form the dual damascene structures. The dual damascene structures are filled with a conductive layer, such as copper or copper alloy. The conductive layer may be formed by, for example, PVD and plating techniques. Excess conductive material is removed by, for example, CMP, forming conductors and contacts in an ILD layer.

The metal line in M₇ level, for example, may be referred to as the top metal line. The via contact in V₆ level, for example, may be referred to as the top via contact. The dimensions of this metal line and its underlying via contact, for example, may be defined at twice the minimum line resolution of the lithography and etch capability for a technology process node, which may be referred to as 2× design rule. For example, the thickness of the top metal line may be at least 2 times greater than the thickness of the metal line below. The top via contact and top metal line include a conductive material, such as Cu. Other suitable configurations and conductive materials for the via contact and metal line may also be useful.

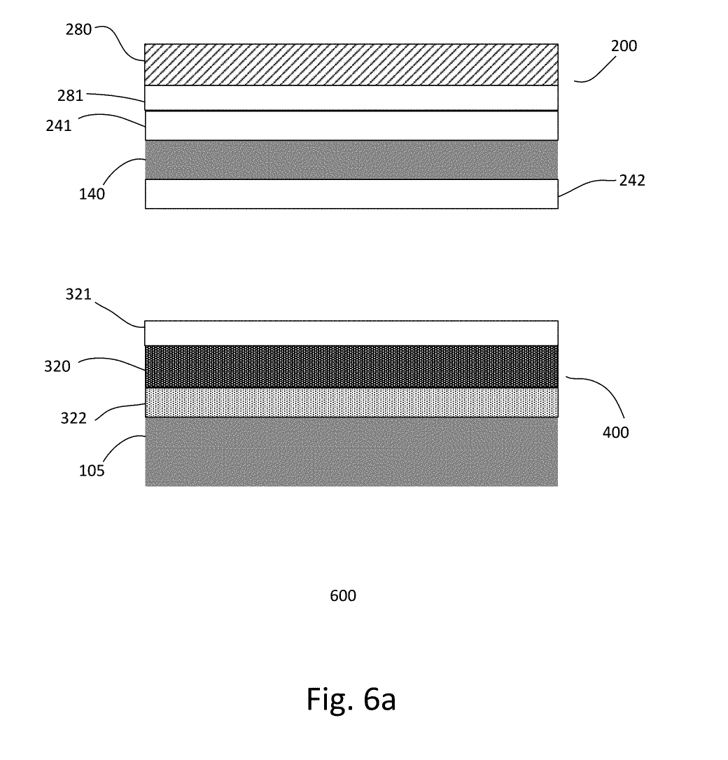

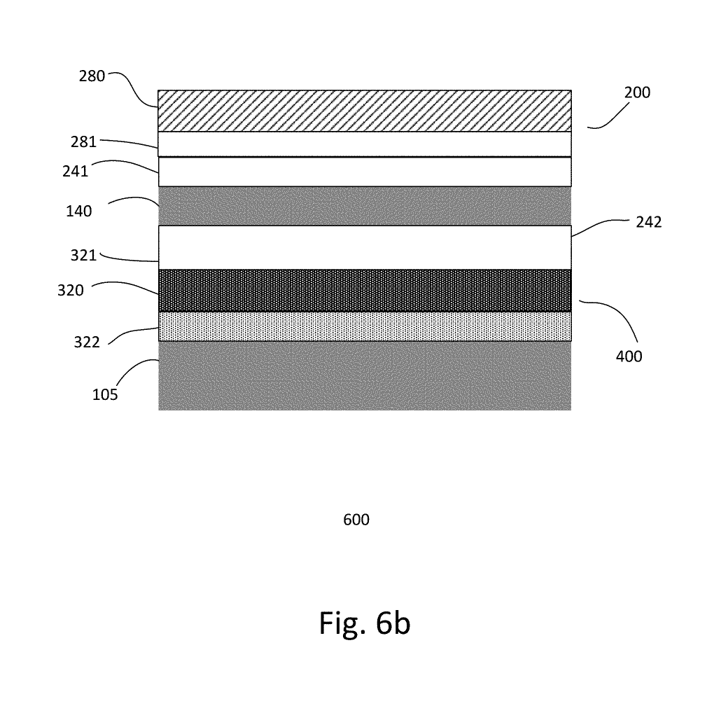

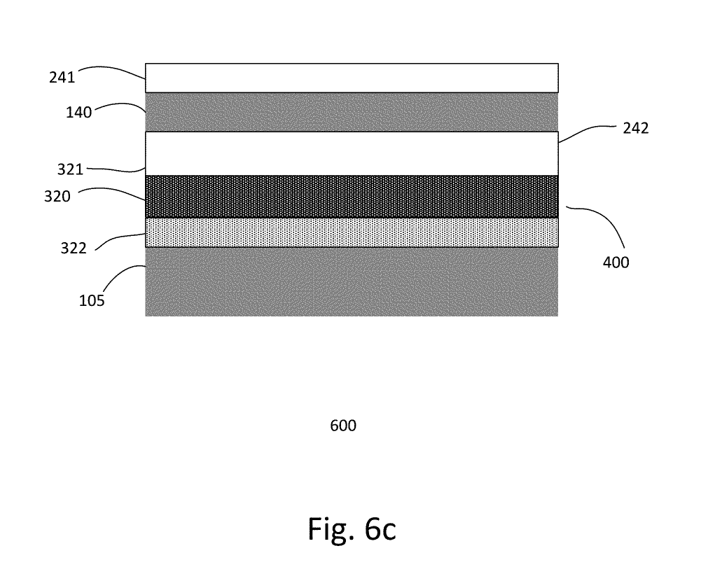

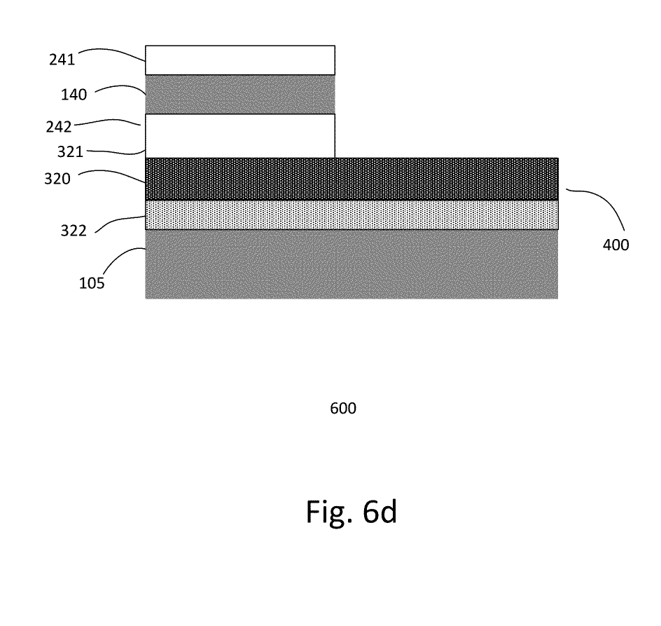

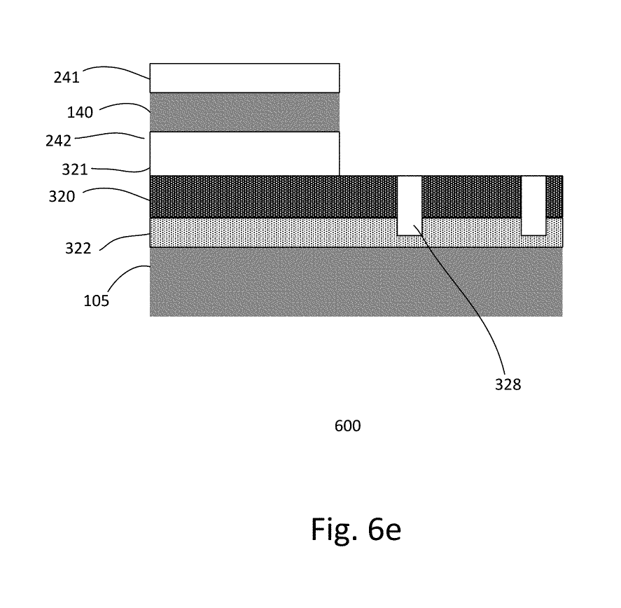

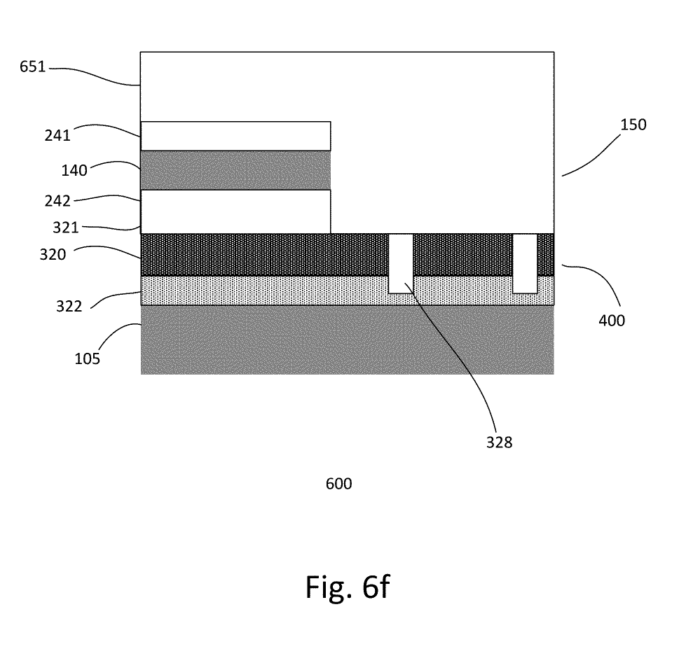

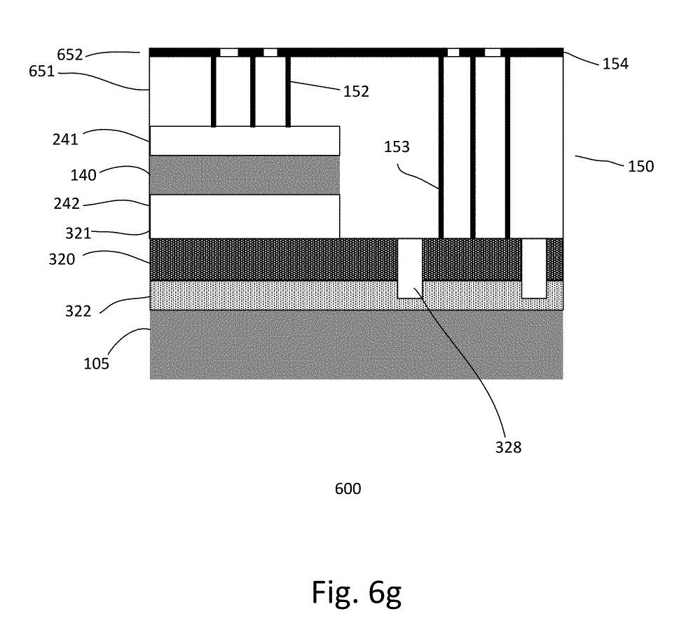

Illustrated in FIGS. 6a-6g, process 600 shows an exemplary Approach 1 of forming a III-V-and-Si substrate device by bonding a processed CMOS substrate with an unprocessed III-V substrate. The III-V substrate is then processed to include III-V devices. In FIG. 6a, the top portion illustrates a CMOS subunit 200 as shown in FIGS. 2a-2d. As described, the CMOS subunit 200 has a CMOS device disposed in, for example, a silicon substrate 140 having bonding dielectric layers disposed on a first surface 241 and a second surface 242. The CMOS subunit 140 bonds on the first surface 241 to a bonding dielectric layer 281 of a carrier substrate 280. Common elements are incorporated by reference and will not be described in detail. The CMOS substrate, for example, silicon or germanium, may be n-type or p-type substrate.

The bottom portion of FIG. 6a illustrates a III-V subunit 400 as described in FIG. 4. Shown in FIG. 6a, the III-V subunit includes a base substrate 105, a buffer layer 322 bonded to the base substrate, and a III-V layer 320 overlying the buffer layer. A bonding dielectric layer 321 covers the III-V layer forming a first surface of the III-V subunit. Common elements are incorporated by reference and will not be further described in detail. The III-V base substrate 105, for example, silicon or germanium, may be n-type or p-type substrate. The III-V subunit 400, for example, GaN or GaA, may be p-type or n-type substrate.

Shown in FIG. 6b, CMOS subunit 200 is bonded to III-V subunit 400 to form a frontend unit. Device 400 is an unprocessed III-V subunit. The CMOS subunit 200 and the III-V subunit 400 are bonded by using the bonding dielectric layer 242 on the CMOS subunit and the bonding dielectric layer 321 on the III-V subunit. The bonding dielectric layers may be one or more dielectric layers. The bonding dielectrics include silicon oxides, silicon nitrides, aluminum oxides, borophosphosilicate (BPSG), TEOS or other dielectric materials. The oxide and nitride layers may be formed by CVD or PECVD. The dielectric materials are provided to enhance planarity and bonding between the Si and III-V substrates as well as to provide electrical isolations between devices. The bonding surfaces require high-quality smoothness. Chemical-mechanical polishing (CMP) may be employed to remove the roughness to obtain smooth surfaces. Cleaning the surfaces may be achieved by hydrofluoric acid etch or a plasma dry etch process.

The CMOS silicon substrate and the III-V substrate are then placed in contact with the bonding dielectric layers in between. Bonding may be performed using anodic or thermo-anodic bonding process. An annealing process at relatively low temperature may be applied. The anneal temperature is slightly above room temperature or about less than 350° C. Multiple anneal cycles may be applied starting from lower temperature to higher temperature, for example, from 150-400° C.

The silicon wafer and the III-V semiconductor wafer are bonded together by using a fast thermal or a thermo-anodic bonding process under low temperature, for example, between 200-450° C. or lower. The bonding dielectric layer is positioned between the first surface of the III-V substrate wafer and the second surface of the CMOS substrate wafer. Bonding dielectric layer comprises solely or a combination of silicon dioxide, doped silicon dioxide, silicon nitride, polysilicon, or amorphous silicon. More preferably, the bonding dielectric layer consists of a silicon nitride layer formed on III-V wafer and a silicon dioxide layer formed on the silicon nitride layer. Other materials may also be used for the bonding dielectric layer.

After the initial bonding, the bonding process gives enough strength in the bond to allow for thinning of III-V wafer and/or CMOS wafer. The thinning process can relieve the thermal stress caused by mismatched thermal coefficients of the substrates. In FIG. 6c, carrier substrate 280 and bonding dielectric layer 281 are removed. Bonding dielectric layer 241 may be thinned on the first surface of the CMOS substrate 140. The thinning process relieves enough stress in the wafers to allow higher temperature processing. A higher temperature anneal may be carried out, for example, at a temperature higher than 350° C. to about 600° C. The high temperature will strengthen the bond between CMOS silicon substrate and III-V substrate and minimize fracture or warpage during subsequent processing. The anneal may be processed from low temperature to gradually increased high temperature. Other anneal processes and temperatures are also useful.

FIG. 6d illustrates the exposure of the III-V substrate by removing part of the CMOS silicon substrate. Photolithography and etch techniques are used. A soft mask layer (not shown) is formed on the dielectric layer 241. The soft mask layer, in one embodiment, is a photoresist layer. The soft mask is patterned to form openings while covering portions of the CMOS substrate layer. To form the openings in the soft mask layer, it may be selectively exposed with an exposure source using a reticle. The pattern of the reticle is transferred to the photoresist layer after exposure by a development process. An anti-reflective coating (ARC) may be provided beneath the resist layer to improve lithographic resolution.

FIG. 6e represents formation of a III-V device of the III-V subunit in a simplified illustration. The devices are discussed in FIGS. 1a-1c and 3a-3d. Common elements are incorporated by reference and will not be described in detail. The process includes, for example, mesa isolation, dielectric passivation, dielectric etching, ohmic metal deposition, metal etch, annealing, Schottky gate formation, field plate formation, and interconnect metal. Other processes may also be useful.

In III-V devices, for example, GaN transistors use metal gates while CMOS transistors use polysilicon or silicide. A positive bias on the gate relative to the source causes a field effect which attracts electrons that complete a bidirectional channel between the drain and the source. Since the electrons are pooled, as opposed to being loosely trapped in a lattice, the resistance of this channel is quite low. When the bias is removed from the gate, the electrons under it are dispersed into the GaN, recreating the depletion region, and once again, giving it the capability to block voltage. The benefit to this mechanism is that there are no minority carriers involved in conduction, and therefore, no reverse recovery losses.

Formation of metal-semiconductor ohmic contacts are made by direct contact between the metals without intervening layers of insulating contamination or oxidation; various techniques are used to form ohmic metal-metal junctions such as sputtering, CVD, PVD, electron beam evaporation, electroplating and others. Ohmic contacts to semiconductors are typically constructed by depositing thin metal films of a carefully chosen composition, possibly followed by annealing to alter the semiconductor bond. Both ohmic contacts and Schottky barriers are dependent on the Schottky barrier height which sets the threshold for the excess energy an electron requires to pass from the semiconductor to the metal. For the junction to admit electrons easily in both directions (ohmic contact), the barrier height must be small in at least some parts of the junction surface. GaN contact materials include Ti/Al/Ni/Au, Pd/Au.

After III-V devices are formed, the process continues to form the frontend unit 110. In FIG. 6f, a dielectric layer 651 serving as a pre-metal dielectric (PMD) layer or first contact layer is formed over the CMOS as part of a dielectric layer 150 for the frontend unit. The dielectric layer may be referred to as PMD 651 or CA level of the BEOL process. The dielectric layers covering the CMOS and III-V subunits are continuous and to the same height. Via contacts 152 and 153 (FIG. 6g) are formed in the CA level dielectric layer by using mask and etch techniques. Via contacts connect the metal silicide contacts of the gate, S/D regions to the metal lines in the ILD layers. Via contacts 152 connect the CMOS to the metal line 652 in the CA level 652. Via contacts 153 connect the III-V to the metal line 154 in the III-V subunit dielectric layer 150. The metal lines 652 and 154 are at the same height and interconnected in the M₁ level.

The contacts may be formed by a single damascene process. Via openings are formed in the dielectric layer using mask and etch techniques. For example, a patterned resist mask with openings corresponding to the vias is formed over the dielectric layer. An anisotropic etch, such as reactive ion etch (ME), is performed to form via openings, exposing contact regions below, such as S/D regions and gates. A conductive layer, such as tungsten, is deposited on the substrate filling the openings. The conductive layer may be formed by CVD. Other suitable techniques may also be useful. A planarization process, such as chemical mechanical planarization (CMP), is performed to remove excess conductive material, leaving contact plugs in the CA level 651 and the dielectric layer 150.

Continuing with FIG. 6g, after forming contacts in the CA level, the process continues to form a conductive layer over the substrate, covering the CA level 651 and the dielectric layer 150. The conductive layer, for example, may be processed to form metal lines of a first metal level M₁ of the first ILD layer. The conductive layer, for example, is an aluminum layer. The conductive layer may be formed by physical vapor deposition (PVD). The conductive layer is processed to form one or more metal lines. The metal lines, in one embodiment, are formed by subtractive etch technique. For example, the conductive layer may be etched to form one or more conductors or metal lines using, for example, photoresist mask, patterning, and etch techniques. Other suitable types of conductive layer or forming techniques may also be useful, depending on the material of the conductive layer. M₁ and CA 652 may be referred to as a lower ILD level.

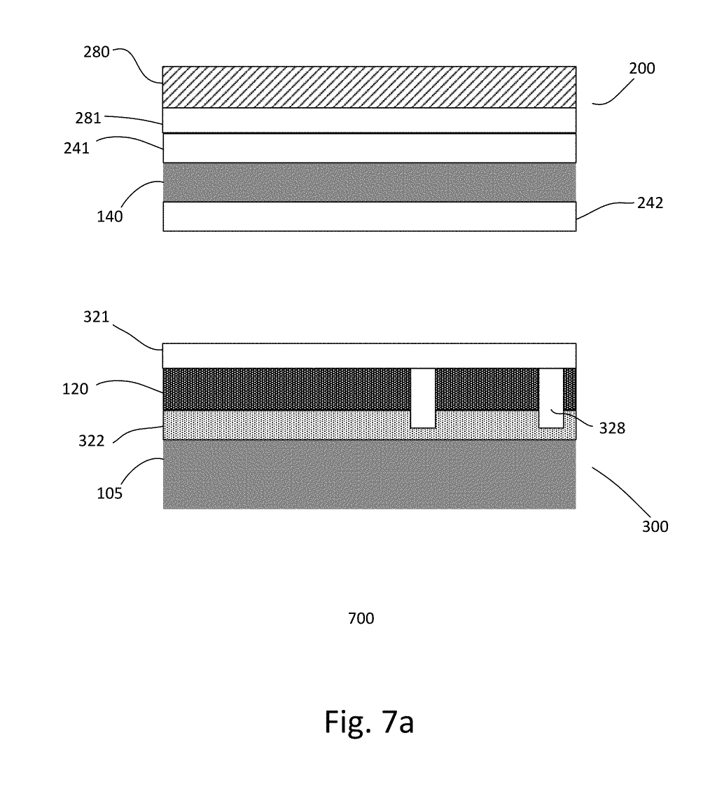

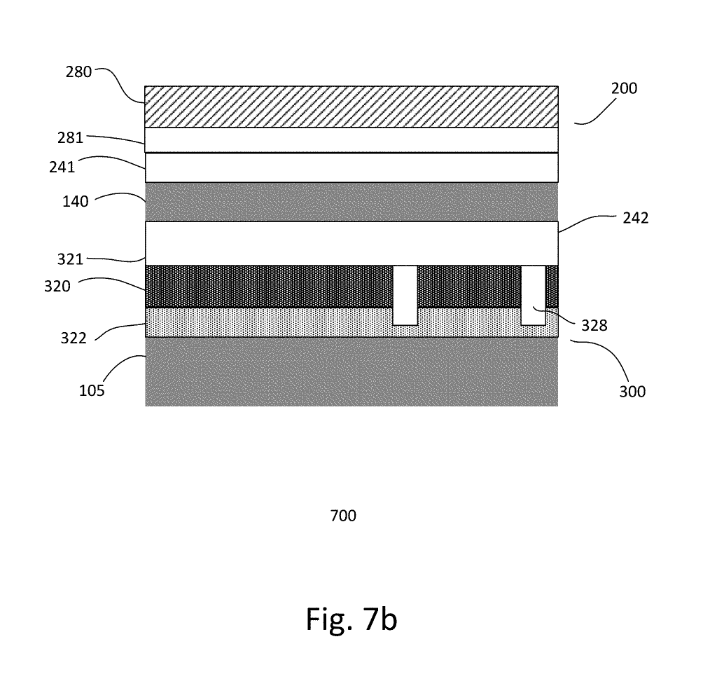

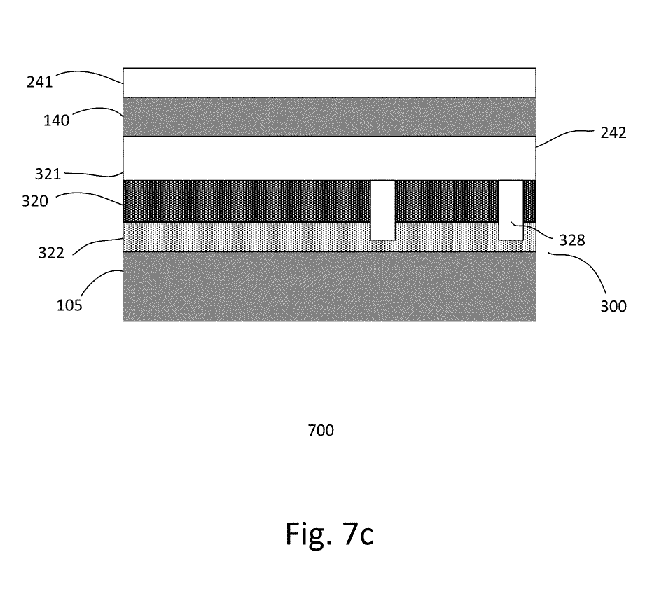

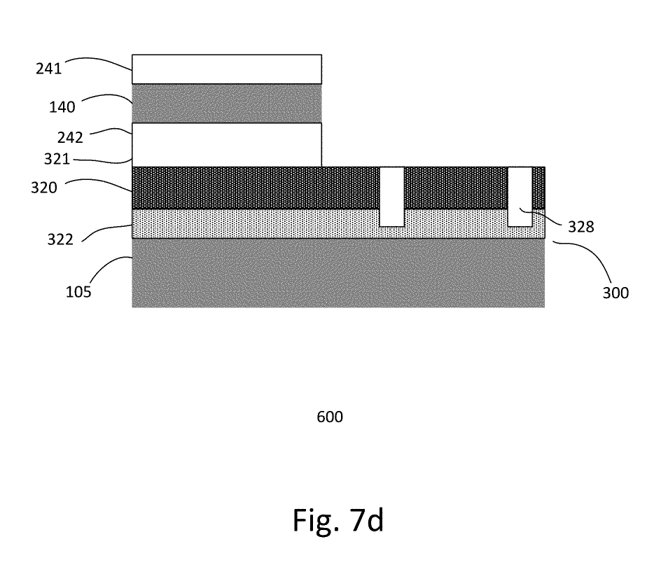

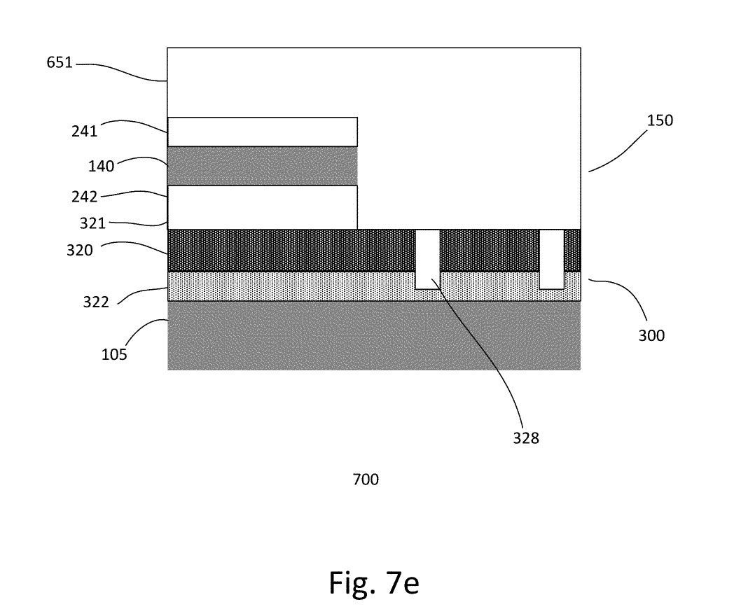

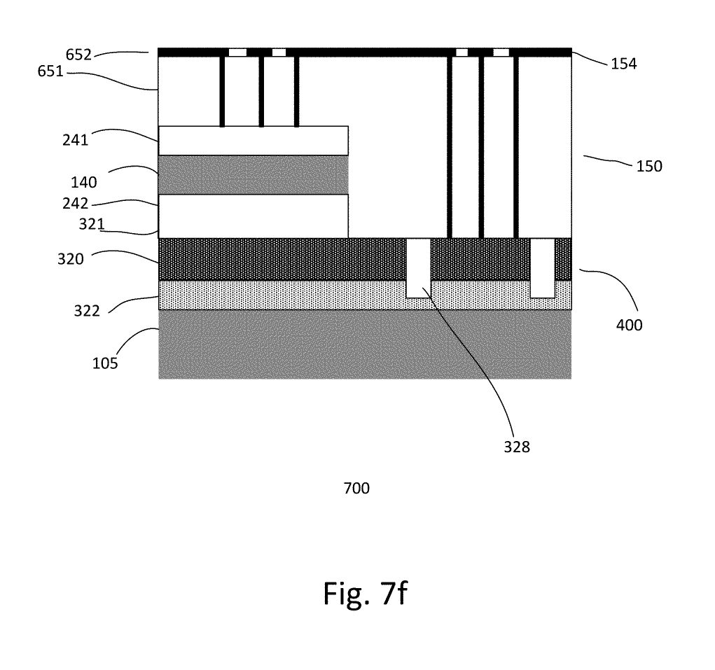

FIGS. 7a-7f show an exemplary Approach 2 of forming a III-V-and-Si substrate device by bonding a processed CMOS subunit 200 to a processed III-V substrate 300. Process 700 is similar to process 600 described in FIGS. 6a-6g. In process 700, a III-V device is already formed in the III-V substrate, forming the processed III-V subunit 300 as described in FIGS. 3a-3d, before bonding to the processed CMOS subunit 200. Common elements in FIGS. 6a-6g and 3a-3d are incorporated by reference and will not be discussed in detail.

Referring to FIG. 7a, a processed CMOS subunit 200 is shown having the carrier substrate 280 bonded on the first surface 241 of CMOS subunit using bonding dielectrics 281 while a bonding dielectric layer is formed on the second surface 242 of the CMOS subunit. A processed III-V subunit is shown having bonding dielectric 321 on the first surface covering the III-V device (not shown) which is disposed between isolation regions 328 in the III-V layer 120 overlying the buffer layer 322 on the base substrate 105. Shown in FIG. 7b, the CMOS subunit is bonded on the second surface to the III-V subunit on the first surface using bonding dielectrics 242 and 321. The carrier substrate 280 and bonding dielectric 281 are removed from the bonded CMOS and III-V subunits (FIG. 7c). The first surface 241 of the CMOS subunit is thinned and polished to release the bonding stress. Photolithography and etching processes expose the III-V device regions where the III-V devices are disposed between isolation regions 328 (FIG. 7d). Pre-metal dielectric (PMD) layers 651 and 150 are formed to cover the CMOS and III-V device regions as shown in FIG. 7e. Silicide or metal contacts are formed in the CMOS and III-V devices (not shown). In FIG. 7f, first level metal lines 652 and 154 are formed on top of the PMD layer forming CA level contacts. Via contacts connect the metal lines 652 and 154 to the CMOS and III-V devices.

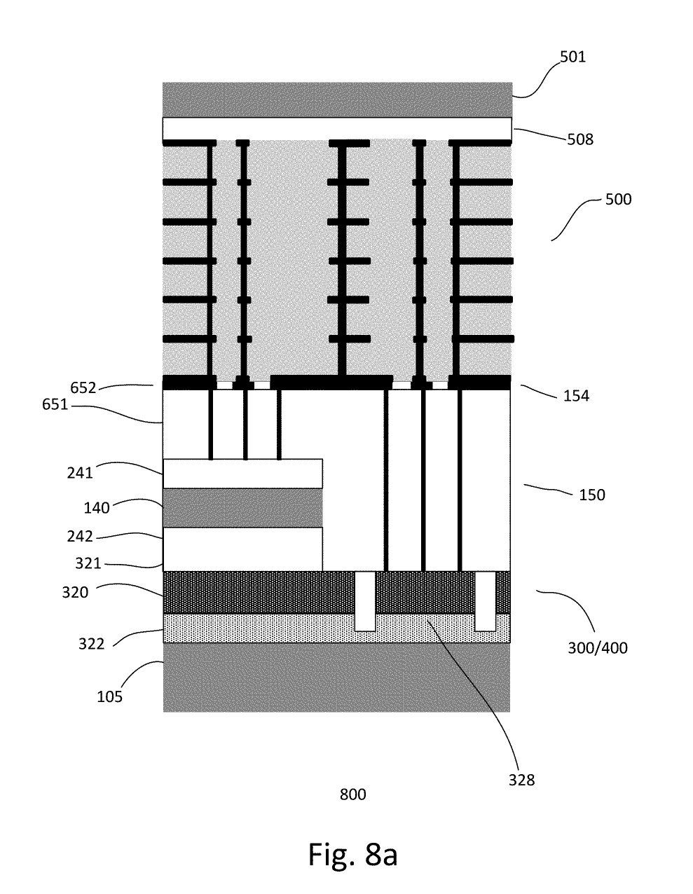

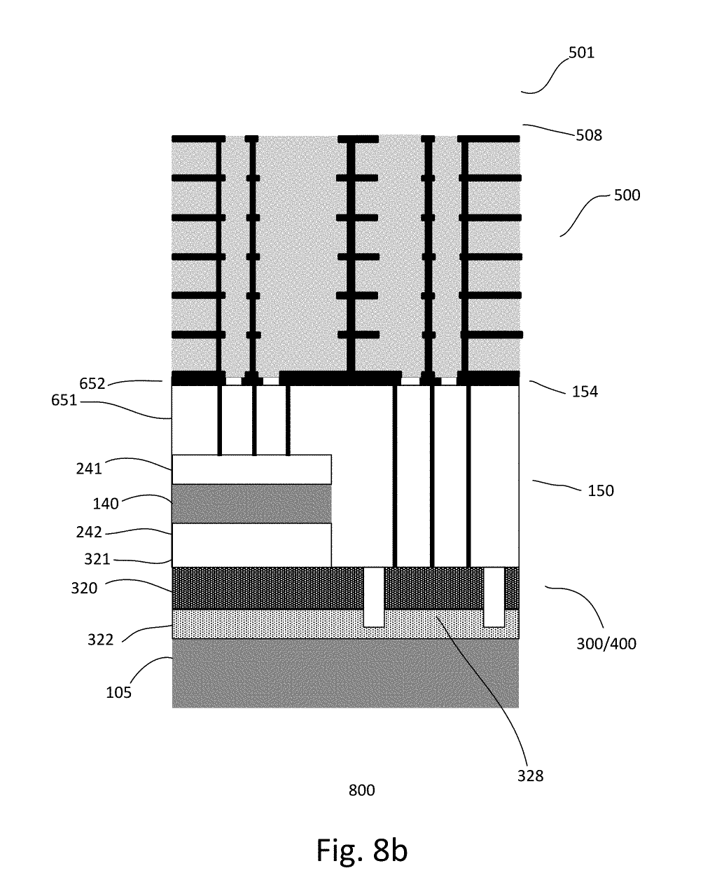

FIGS. 8a-8b illustrate bonding a frontend unit, for example, formed in Approach 1 or Approach 2 to a backend unit. Frontend units formed in processes 600/700 are provided with first level metal lines 652 and 154 in PMD or CA level 651 or dielectric layer 150 as shown in FIGS. 6g and 7f Backend unit formed in process 500 is provided with a backend carrier substrate as shown in FIG. 5b. Direct wafer bonding is applied to bond the backend unit (interconnect unit) and frontend units at room temperature by adhesive forces without additional materials. Different bonding schemes may be employed, for example, oxide bonding with precision alignment where two vias are necessary to contact the two layers, oxide bonding with alignment by via capacitance, or hybrid oxide metal patterned surface.

For copper bonding ultra-high vacuum (UHV) in a UHV plasma with an argon (Ar) ion beam is used to remove the copper oxide. The bonding is then conducted at room temperature anneal under high vacuum, a low temperature around 200° C. Direct bonding of oxide/copper surfaces at room temperature and ambient air may also be used.

The process continues by removing the backend carrier substrate 501 and a portion of the dielectric layer 508 as shown in FIG. 8b. In one embodiment, a portion of the backend carrier substrate is removed using a backgrinding process. A capping layer (not shown) may cover the upper ILD level. A pad dielectric layer or level having a pad interconnect is disposed over the capping layer. The pad interconnect includes a pad via contact in the pad via level and a contact pad in the pad contact level. The pad via contact is electrically coupled to the interconnect in the upper ILD level. The pad interconnect, in one embodiment, is an aluminum pad interconnect. Other suitable conductive materials, such as but not limited to copper, may also be used to serve as the pad interconnect. In one embodiment, the pad via contact and the contact pad may be formed of the same material, for example aluminum. The pad via contact and contact pad may be an integral unit, for example, formed by a dual damascene process. The dual damascene process may be via first or via last process. The process continues to form the device. The process completes with final passivation, dicing, assembly and packaging. Other processes may also be included.

The embodiments as described in this disclosure result in various advantages. For example, high yield is possible with almost no breakage of GaN on Si wafers because the metal layers are fabricated separately and bonded to the GaN integrated CMOS wafers. The process illustrates a new approach to directly integrate multiple wafers which are processed in parallel, including interconnect metal layers. For example, six pairs of interconnect metal layers can be separated by thick dielectrics. The process time is reduced because the interconnect metal layers can be processed in parallel with the GaN integrated CMOS wafers. Si circuits, III-V wafer bonding and III-V devices can be fabricated using existing techniques and manufacturing equipment. For example, Si CMOS circuits can be fabricated by conventional CMOS or BCD (bipolar CMOS DMOS) processing. Bond pads are designed to directly integrate III-V wafers. The originally complicated process flows can be simplified and, thus, lower cost. The present embodiments can reduce breakage risk of Si III-V bonded wafer, produce large, high-density III-V substrate arrays and high-performance microprocessors.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A method of forming a device comprising:
forming a CMOS subunit having first and second surfaces comprising a silicon substrate, a CMOS device disposed on a first surface of the silicon substrate, a first bonding dielectric covering the CMOS device forming the first surface of the CMOS subunit, and a second bonding dielectric covering a second surface of the silicon substrate forming the second surface of the CMOS subunit;
forming a III-V subunit having a first surface comprising a III-V substrate, a III-V device disposed on the III-V substrate, a first bonding dielectric covering the III-V device forming the first surface of the III-V subunit;
bonding the second surface of the CMOS subunit to the first surface of the III-V subunit;
forming a frontend unit comprising pre-metal dielectric (PMD) layers disposed on the first surfaces of the CMOS and III-V subunits to a same height, via contacts disposed in the PMD layers, and metal lines disposed on the PMD layers forming a first surface of the frontend unit wherein the metal lines are connected to the CMOS and the III-V subunits using the via contacts;
forming a backend unit in parallel with the frontend unit comprising a backend carrier substrate, a dielectric layer disposed on the backend carrier substrate, and interlevel dielectric (ILD) levels disposed on the dielectric layer wherein the ILD levels are formed sequentially from an uppermost ILD level to a lowest ILD level forming a first surface of the backend unit; and
bonding the backend unit on the first surface to the frontend unit on the first surface.

2. The method of forming a device in claim 1, the CMOS subunit further comprising:
bonding a carrier substrate to the second surface of the CMOS subunit by a bonding dielectric formed on the carrier substrate.

3. The method of forming a device in claim 1, the III-V subunit further comprising:
providing a base substrate;
forming a buffer layer on the base substrate wherein a III-V layer is disposed over the buffer layer; and
covering the III-V layer with a bonding dielectric forming the first surface of the III-V subunit.

4. The method of forming a device in claim 1, the III-V subunit further comprising:
providing a base substrate;
forming a buffer layer on the base substrate wherein a III-V layer is disposed over the buffer layer;
forming isolation regions in the III-V layer extending into the buffer layer defining III-V device regions;
forming III-V devices in the III-V device regions of the III-V layer; and
covering the III-V devices and the III-V layer with bonding dielectrics forming the first surface of the III-V subunit.

5. The method of forming a device in claim 1, wherein each ILD level includes a metal level comprising metal lines and a via level comprising via contacts.

6. The method of forming a device in claim 1, the bonding dielectrics comprising silicon nitrides, silicon oxides, aluminum oxides, or a combination thereof.

7. The method of forming a device in claim 1, the bonding comprising low temperature bonding.

8. The method of forming a device in claim 2, the carrier substrate comprising silicon.

9. The method of forming a device in claim 3, the III-V subunit comprising GaN on silicon.

10. The method of forming a device in claim 1, further comprising:
forming metal lines on the pre-metal dielectric layers;
forming metal lines on the pre-metal dielectric layers connecting to the CMOS and the III-V subunits using via contacts; and
bonding the metal lines to the first surface of the backend unit.

11. A method of forming a device, comprising:
forming a CMOS subunit having first and second surfaces comprising a silicon substrate, a CMOS device disposed on a first surface of the silicon substrate, a first bonding dielectric covering the CMOS device forming the first surface of the CMOS subunit, and a second bonding dielectric covering a second surface of the silicon substrate forming the second surface of the CMOS subunit;
forming a III-V subunit having a first surface comprising a III-V substrate, a III-V device disposed on the III-V substrate, a first bonding dielectric covering the III-V device forming the first surface of the III-V subunit;
forming a frontend unit comprising bonding the second surface of the CMOS subunit to the first surface of the III-V subunit, wherein the first surface of the CMOS subunit forming a first surface of the frontend unit;
forming a backend unit in parallel with the frontend unit comprising a backend carrier substrate, a dielectric layer disposed on the backend carrier substrate, and interlevel dielectric (ILD) levels disposed on the dielectric layer wherein the ILD levels are formed sequentially from an uppermost ILD level to a lowest ILD level forming a first surface of the backend unit; and
bonding the backend unit on the first surface to the frontend unit on the first surface.

12. The method of forming a device of claim 11, forming the frontend unit further comprising:
patterning and etching the CMOS subunit to expose the III-V layer;
forming isolation regions (STI) to define III-V device regions in the III-V layer;
forming a III-V device in the III-V device region;
forming a dielectric layer over the CMOS subunit and the III-V subunit to a same height; and
forming first level metal lines connecting to the CMOS and the III-V subunits using via contacts.

13. The method of forming a device of claim 11, forming the frontend unit further comprising:
forming the first surface of the III-V subunit having a III-V device disposed on the III-V layer covered by a bonding dielectric before bonding to the CMOS subunit;
bonding the second surface of the CMOS subunit to the first surface of the III-V subunit;
forming a dielectric layer on the first surfaces of the CMOS and the III-V subunits to a same height; and
forming first level metal lines in the dielectric layer connecting to the CMOS and the III-V subunits using via contacts.

14. The method of forming a device in claim 2, further comprising:
removing the carrier substrate after bonding the CMOS and the III-V subunits; and
thinning the bonding dielectrics on the first surface of the CMOS subunit before forming the pre-metal dielectric (PMD) layer, a first level metal lines, and bonding to the backend unit.

15. The method of forming a device of claim 11, further comprising:
removing the backend carrier substrate after bonding the frontend and the backend units.

16. The method of forming a device of claim 11, the bonding dielectrics comprise silicon oxides, silicon nitrides, aluminum oxides, or a combination thereof.

17. The method of forming a device of claim 11, the bonding comprising low temperature bonding.

18. The method of forming a device of claim 17, bonding is followed by a thermal anneal.

19. The method of forming a device of claim 18, bonding is performed from low temperature to gradually increased high temperature.

20. The method of forming a device of claim 11, the CMOS device includes a polysilicon or metal silicide gate, and the III-V device includes a metal gate.
